(19) United States
(12) Patent Application Publication
(10) Pub. No.: US 2022/0115623 A1
(43) Pub. Date: Apr. 14, 2022

(54) OLED DISPLAY PANEL AND PREPARATION METHOD THEREOF

(71) Applicant: Wuhan China Star Optoelectronics Semiconductor Display Technology Co., Ltd., Wuhan, Hubei (CN)

(72) Inventors: Liang FANG, Wuhan, Hubei (CN); Ding DING, Wuhan, Hubei (CN)

(73) Assignee: Wuhan China Star Optoelectronics Semiconductor Display Technology Co., Ltd., Wuhan, Hubei (CN)

(21) Appl. No.: 17/262,723

(22) PCT Filed: Jun. 15, 2020
(86) PCT No.: PCT/CN2020/096121

§ 371 Date: Jan. 24, 2021

(30) Foreign Application Priority Data
Apr. 29, 2020 (CN) 202010356377.6

(51) Int. Cl. H01L 51/52; H01L 51/56; H01L 27/32

(52) U.S. Cl. CPC H01L 51/5253; H01L 27/3246; H01L 27/3258; H01L 51/56

(57) ABSTRACT

An organic light-emitting diode (OLED) display panel and a preparation method thereof are provided. The OLED display panel comprises an array substrate structure including an opening area, a transition area and a display area, a light emitting layer, and an encapsulation layer. At least one channel is formed in a portion of the array substrate structure corresponding to the transition area, a closed structure is formed by the channel surrounding the opening, and at least one undercut structure is provided on a sidewall of the channel. The light emitting layer and the encapsulation layer cover the channel and extend to an edge of the opening, and a fault structure is formed at the undercut structure by the light emitting layer.

### FIELD OF INVENTION

The present disclosure relates to the technical field of display, and in particular, relates to an organic light-emitting diode (OLED) display panel and a preparation method thereof.

### BACKGROUND OF INVENTION

At present, in the technical field of display, in order to increase an effective display area of display devices, the design of an under-screen camera has gradually become the mainstream technology. The design of the under-screen camera is to set the camera component in an opening area, and realize a camera function by implementing an opening design in the opening area.

### Technical Problem

Since a light emitting layer in the OLED display panel is usually prepared by an entire surface evaporation process, there is a film layer with a low light-transmitting effect, such as a cathode layer, in the light emitting layer. Thus, it is necessary to cut the light emitting layer corresponding to the opening area by laser to improve an imaging effect. However, a lateral edge of the light emitting layer is exposed after cutting, so that external water and oxygen invade the interior of the OLED device through the lateral edge of the light emitting layer, thereby affecting the stability of the display panel.

### SUMMARY OF INVENTION

### Solution to Problem

An object of the present disclosure is to provide an organic light-emitting diode (OLED) display panel and a preparation method thereof to improve the effect of cutting on the light emitting layer by, thereby improving the stability of the display panel.

The present disclosure provides an OLED display panel, which comprises an array substrate structure, a light emitting layer, and an encapsulation layer arranged in sequence, wherein the array substrate structure comprises an opening area, a transition area surrounding the opening area, and a display area surrounding the transition area, and an opening is formed in a portion of the array substrate structure corresponding to the opening area;

wherein at least one channel is formed in a portion of the array substrate structure corresponding to the transition area, a closed structure is formed by the channel surrounding the opening, and at least one undercut structure is provided on a sidewall of the channel;

wherein the light emitting layer and the encapsulation layer cover the channel and extend to an edge of the opening, and a fault structure is formed at the undercut structure by the light emitting layer;

wherein the array substrate structure includes a base substrate, a buffer layer, a first gate metal layer, a dielectric insulating layer, a first source-drain metal layer, and a protective layer arranged in sequence, and the channel at least passes through the protection layer and the first source-drain metal layer.

In the OLED display panel of the present disclosure, the protective layer includes a first protrusion portion, the first protrusion portion extends into the channel and is suspended from the first source-drain metal layer, and the first protrusion portion and a sidewall of the first source-drain metal layer define the undercut structure.

In the OLED display panel of the present disclosure, the channel passes through the protective layer, the first source-drain metal layer, the dielectric insulating layer, and the first gate metal layer;

the protective layer includes a first protrusion portion, the first protrusion portion extends into the channel and is suspended from the first source-drain metal layer, and the first protrusion portion and a sidewall of the first source-drain metal layer define the undercut structure;

the dielectric insulating layer includes a second protrusion portion, the second protrusion portion extends into the channel and is suspended from the first gate metal layer, and the second protrusion portion and a sidewall of the first gate metal layer define another undercut structure.

In the OLED display panel of the present disclosure, the channel passes through the protective layer, the first source-drain metal layer, the dielectric insulating layer, and the first gate metal layer;

the first source-drain metal layer includes a first protrusion portion, the first protrusion portion extends into the channel and is suspended from the protective layer;

the first gate metal layer includes a second protrusion portion, the second protrusion portion extends into the channel and is suspended from the dielectric insulating layer;

the first protrusion portion and a sidewall of the dielectric insulating layer define the undercut structure.

In the OLED display panel of the present disclosure, the array substrate structure includes:

an active layer disposed on the buffer layer and located in the display area;

a first gate insulating layer disposed on the buffer layer, wherein a portion of the first gate insulating layer located in the display area covers the active layer;

a second gate metal layer disposed on the first gate insulating layer and located in the display area;

a second gate insulating layer disposed on the first gate insulating layer, wherein a portion of the second gate insulating layer located in the display area covers the second gate metal layer;

the first gate metal layer disposed on the second gate insulating layer;

the dielectric insulating layer disposed on the first gate metal layer;

the first source-drain metal layer disposed on the dielectric insulating layer;

the protective layer provided on the first source-drain metal layer;

a second source-drain metal layer disposed on the protective layer and located in the display area;

a first flat layer disposed on the protective layer, wherein a portion of the first flat layer located in the display area covers the second source-drain metal layer, and a portion of the first flat layer located in the transition area extends along the protective layer to an edge of the opening;

a second flat layer disposed on the first flat layer and covering a portion of the first flat layer located in the transition area;

a pixel definition layer disposed on a portion of the first flat layer located in the display area.

The present disclosure further provides organic light-emitting diode (OLED) display panel, which comprises an array substrate structure, a light emitting layer, and an encapsulation layer arranged in sequence, wherein the array substrate structure comprises an opening area, a transition area surrounding the opening area, and a display area surrounding the transition area, and an opening is formed in a portion of the array substrate structure corresponding to the opening area;

wherein at least one channel is formed in a portion of the array substrate structure corresponding to the transition area, a closed structure is formed by the channel surrounding the opening, and at least one undercut structure is provided on a sidewall of the channel;

wherein the light emitting layer and the encapsulation layer cover the channel and extend to an edge of the opening, and a fault structure is formed at the undercut structure by the light emitting layer.

In the OLED display panel of the present disclosure, the array substrate structure includes a first gate metal layer, a dielectric insulating layer, a first source-drain metal layer, and a protective layer arranged in sequence, and the channel at least passes through the protection layer and the first source-drain metal layer.

In the OLED display panel of the present disclosure, the channel passes through the protective layer, the first source-drain metal layer;

the protective layer includes a first protrusion portion, the first protrusion portion extends into the channel and is suspended from the first source-drain metal layer, and the first protrusion portion and a sidewall of the first source-drain metal layer define the undercut structure.

In the OLED display panel of the present disclosure, the channel passes through the protective layer, the first source-drain metal layer, the dielectric insulating layer, and the first gate metal layer;

the protective layer includes a first protrusion portion, the first protrusion portion extends into the channel and is suspended from the first source-drain metal layer, and the first protrusion portion and a sidewall of the first source-drain metal layer define the undercut structure;

the dielectric insulating layer includes a second protrusion portion, the second protrusion portion extends into the channel and is suspended from the first gate metal layer, and the second protrusion portion and a sidewall of the first gate metal layer define another undercut structure.

In the OLED display panel of the present disclosure, the channel passes through the protective layer, the first source-drain metal layer, the dielectric insulating layer, and the first gate metal layer;

the first source-drain metal layer includes a first protrusion portion, the first protrusion portion extends into the channel and is suspended from the protective layer;

the first gate metal layer includes a second protrusion portion, the second protrusion portion extends into the channel and is suspended from the dielectric insulating layer;

the first protrusion portion and a sidewall of the dielectric insulating layer define the undercut structure.

In the OLED display panel of the present disclosure, the array substrate structure includes:

a base substrate;

a buffer layer disposed on the base substrate;

an active layer disposed on the buffer layer and located in the display area;

a first gate insulating layer disposed on the buffer layer, wherein a portion of the first gate insulating layer located in the display area covers the active layer;

a second gate metal layer disposed on the first gate insulating layer and located in the display area;

a second gate insulating layer disposed on the first gate insulating layer, wherein a portion of the second gate insulating layer located in the display area covers the second gate metal layer;

the first gate metal layer disposed on the second gate insulating layer;

the dielectric insulating layer disposed on the first gate metal layer;

the first source-drain metal layer disposed on the dielectric insulating layer;

the protective layer provided on the first source-drain metal layer;

a second source-drain metal layer disposed on the protective layer and located in the display area;

a first flat layer disposed on the protective layer, wherein a portion of the first flat layer located in the display area covers the second source-drain metal layer, and a portion of the first flat layer located in the transition area extends along the protective layer to an edge of the opening;

a second flat layer disposed on the first flat layer and covering a portion of the first flat layer located in the transition area;

a pixel definition layer disposed on a portion of the first flat layer located in the display area.

The present disclosure provides a preparation method of an OLED display panel, which comprises steps of:

providing a base substrate;

forming an array substrate structure on the base substrate, wherein the array substrate structure comprises an opening area, a transition area surrounding the opening area, and a display area surrounding the transition area;

forming at least one channel in a portion of the array substrate structure corresponding to the transition area by using an etching process, wherein a closed structure is formed by the channel surrounding the opening area;

forming at least one undercut structure on a sidewall of the channel by using an etching process;

forming a light emitting layer on the array substrate structure, wherein the light emitting layer covers the channel and extends to an edge of the opening area;

forming an encapsulation layer on the light emitting layer;

forming an opening in a portion of the array substrate structure corresponding to the opening area.

In the preparation method of the present disclosure, forming at least one undercut structure on a sidewall of the channel by using an etching process comprises step of:

adopting a wet etching process to etch the sidewall of the channel to form the undercut structure.

In the preparation method of the present disclosure, forming an array substrate structure on the base substrate comprises steps of:

providing a base substrate;

forming a buffer layer on the base substrate;

forming an active layer on the buffer layer by patterning, wherein the active layer is located in the display area;

forming a first gate insulating layer on the buffer layer, wherein a portion of the first gate insulating layer located in the display area covers the active layer;

forming a first gate metal layer on the first gate insulating layer by patterning, wherein the first gate metal layer is located in the display area;

forming a second gate insulating layer on the first gate insulating layer, wherein a portion of the second gate insulating layer located in the display area covers the first gate metal layer;

forming a second gate metal layer on the second gate insulating layer;

forming a dielectric insulating layer on the second gate metal layer;

forming another opening in the opening area, wherein the opening at least passes through the dielectric insulating layer, the second gate metal layer, the second gate insulating layer, and the first gate insulating layer, and extends to the transition area;

forming a first source-drain metal layer on the dielectric insulating layer;

forming a protective layer on the first source-drain metal layer;

forming a second source-drain metal layer on the protective layer by pattering, wherein the second source-drain metal layer is located in the display area;

forming a first flat layer on the protective layer by patterning, wherein a portion of the first flat layer located in the display area covers the second source-drain metal layer, and a portion of the first flat layer located in the transition area extends along the protective layer to an edge of the opening;

forming a second flat layer on the first flat layer by patterning, wherein the second flat layer covers a portion of the first flat layer located in the transition area;

forming a pixel definition layer on a portion of the first flat layer located in the display area by patterning.

In the preparation method of the present disclosure, after forming a pixel definition layer on a portion of the first flat layer located in the display area by patterning, the step comprises:

forming at least one channel in a portion of the array substrate structure corresponding to the transition area by suing an etching process, wherein a closed structure is formed by the channel surrounding the opening area, and the channel passes through the protective layer, the first source-drain metal layer, the dielectric insulating layer, and the second gate metal layer;

wherein an acidic solution is used as an etching solution, and a sidewall of the channel is etched by a wet etching process to form the undercut structure; the protective layer includes a first protrusion portion, the first protrusion portion extends into the channel and is suspended from the first source-drain metal layer, and the first protrusion portion and a sidewall of the first source-drain metal layer define the undercut structure;

the dielectric insulating layer includes a second protrusion portion, the second protrusion portion extends into the channel and is suspended from the first gate metal layer, and the second protrusion portion and a sidewall of the second gate metal layer define another undercut structure.

### Advantageous Effects of Invention

Compared with the OLED display panel in the prior art, the OLED display panel of the present disclosure is provided with an undercut structure on the metal layer of the transition area, so that the light emitting layer is broken at the undercut structure. When the encapsulation layer is used to protect the breakage of the light emitting layer, the path of external water and oxygen invading the OLED device along the light emitting layer is extended, and the stability of the display panel is improved.

### DESCRIPTION OF DRAWINGS

In order to more clearly illustrate technical solutions in embodiments of the present disclosure, the drawings used in the description of the embodiments will be briefly introduced below. Obviously, the drawings in the following description are only some embodiments of the present disclosure, and those skilled in the art can obtain other drawings according to these drawings without any creative effort.

FIG. 1 is a schematic diagram of an organic light-emitting diode (OLED) display panel according to an embodiment of the present disclosure.

FIG. 2 is a schematic diagram of the cross-sectional structure along line AA′ in FIG. 1.

FIG. 3 is a flow chart of a method for manufacturing an OLED display panel according to an embodiment of the present disclosure.

FIG. 4A to FIG. 4K are schematic structural diagrams obtained sequentially from steps S201 to S207 in the method for manufacturing an OLED display panel according to an embodiment of the present disclosure.

### DETAILED DESCRIPTION OF PREFERRED EMBODIMENTS

The technical solutions in the embodiments of the present disclosure will be described clearly and completely with reference to the drawings in the embodiments of the present disclosure. Obviously, the described embodiments are only a part of the embodiments of the present disclosure, but not all the embodiments. Based on the embodiments in the present disclosure, all other embodiments obtained by those skilled in the art without making creative work fall within the protection scope of the present disclosure.

In the description of the present disclosure, it should be understood that the terms “center”, “longitudinal”, “transverse”, “length”, “width”, “thickness”, “upper”, “lower”, “front”, “back, “left”, “right”, “vertical”, “horizontal”, “top”, “bottom”, “inner”, “outer”, “clockwise”, “counterclockwise” etc. The indicated orientation or positional relationship is based on the orientation or positional relationship shown in the drawings, just to facilitate the description of the present disclosure and simplify the description. It does not indicate or imply that the referred device or element must have a specific orientation, be constructed and operated in a specific orientation, and therefore cannot be construed as a limitation of the present disclosure. In addition, the terms “first” and “second” are used for description purposes only, and cannot be understood as indicating or implying relative importance or implicitly indicating the number of indicated technical features. Thus, features defined as “first” and “second” may explicitly or implicitly include one or more of the features. In the description of this present disclosure, the meaning of “plurality” is two or more, unless otherwise specifically limited.

In the description of the present disclosure, it should be noted that, unless otherwise clearly specified and limited, the terms “installation”, “connecting”, “connection” should be broadly understood. For example, it can be a fixed connection, a detachable connection, or an integral connection; it can be a mechanical connection, an electrical connection, or can communicate with each other; it can be directly connected or indirectly connected through an intermediate medium; it can be the connection between two elements or the interaction between two elements. Those of ordinary skill in the art can understand the specific meanings of the above terms in the present disclosure according to specific situations.

In the present disclosure, unless otherwise clearly specified and defined, the first feature “on” or “below” the second feature may include the direct contact of the first and second features, it may also include that the first and second features are not in direct contact but are in contact with another feature between them. Moreover, the first feature is “above”, “above” and “above” the second feature includes that the first feature is directly above and diagonally above the second feature, or it simply means that the first feature has a higher level than the second feature. The first feature is “below”, “below” and “below” the second feature includes that the first feature is directly below and obliquely below the second feature, or it simply means that the level of the first feature is less than the second feature.

The following disclosure provides many different implementations or examples for implementing different structures of the present disclosure. In order to simplify the disclosure of the present disclosure, the components and settings of specific examples are described below. Of course, they are only examples, and the purpose is not to limit the present disclosure. In addition, this present disclosure may repeat reference numerals and/or reference letters in different examples, this repetition is for simplicity and clarity, and does not in itself indicate the relationship between the various embodiments and/or settings discussed. Furthermore, the present disclosure provides examples of various specific processes and materials, but those of ordinary skill in the art may be aware of the application of other processes and/or the use of other materials.

It should be noted that the camera opening area in the present disclosure may be located at different positions of an organic light-emitting diode (OLED), including the middle of the display panel or the edge of the display panel. The OLED display panel of this embodiment is only described by taking the camera opening area in the middle of the display panel as an example, but it is not limited to this.

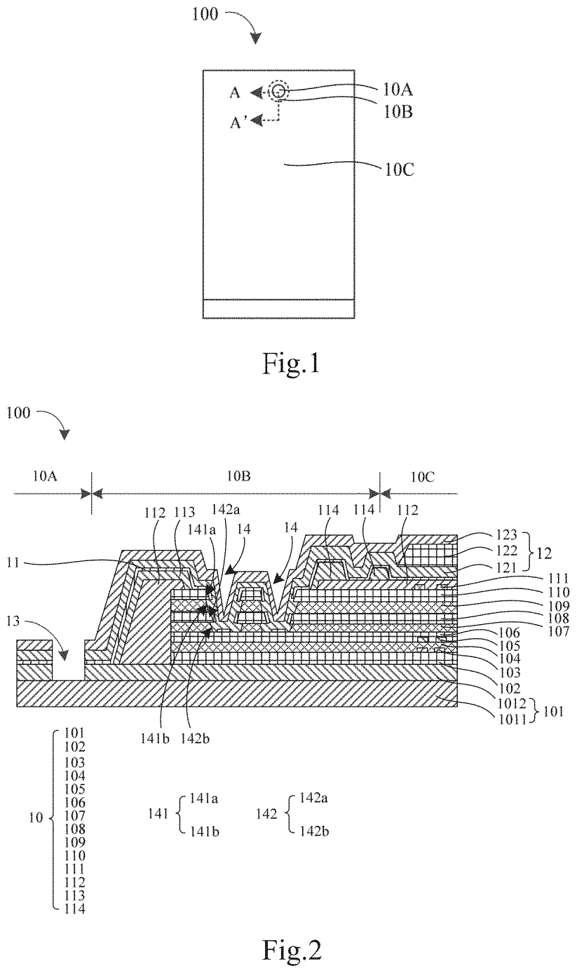

Refer to FIG. 1 and FIG. 2. FIG. 1 is a schematic diagram of an organic light-emitting diode (OLED) display panel according to an embodiment of the present disclosure, and FIG. 2 is a schematic diagram of the cross-sectional structure along line AA′ in FIG. 1.

The present disclosure provides an OLED display panel 100, which comprises an array substrate structure 10, a light emitting layer 11, and an encapsulation layer 12 arranged in sequence, wherein the array substrate structure 10 comprises an opening area 10A, a transition area 10B surrounding the opening area 10A, and a display area 10C surrounding the transition area 10B. An opening 13 is formed in a portion of the array substrate structure 10 corresponding to the opening area 10A. At least one channel 14 is formed in a portion of the array substrate structure 10 corresponding to the transition area 10B, a closed structure is formed by the channel 14 surrounding the opening 13, and at least one undercut structure 141 is provided on a sidewall of the channel 14. The light emitting layer 11 and the encapsulation layer 12 cover the channel 13 and extend to an edge of the opening 13, and a fault structure is formed at the undercut structure 141 by the light emitting layer 11.

Therefore, the OLED display panel provided by the embodiment of the present disclosure forms the fault structure by providing the channel 14 with the undercut structure 141 in the transition area 10B, so that the light emitting layer 11 breaks at the undercut structure 141 to form the fault structure. Furthermore, when the encapsulation layer 12 is used to protect the breakage of the light emitting layer 11, the path for external water and oxygen to invade the OLED device along the light emitting layer 11 is extended, and the stability of the display panel is improved.

It may be understood that, in the embodiment, the encapsulation layer 12 includes a first inorganic layer 121, an organic layer 122, and a second inorganic layer 123 that are arranged in sequence. The organic layer 122 is located in the display area 10C.

Optionally, the number of channels 14 is two. In addition, the number of the channels 14 may also be selected according to specific circumstances, and the embodiment is not understood as a limitation to the present disclosure.

Specifically, the array substrate structure 10 includes a first gate metal layer 107, a dielectric insulating layer 108, a first source-drain metal layer 109, and a protective layer 110 that are arranged in sequence. The channel 14 at least passes through the protective layer 110 and the first source-drain metal layer 109.

Due to the existence of the undercut structure 141, the light emitting layer 11 in the channel 14 may break at the undercut structure 141, so that the light emitting layer 11 forms the fault structure on the sidewall of the channel 14. When the encapsulation layer 12 is used to protect the breakage of the light emitting layer 11, the path of external water and oxygen through the transition area 10B is increased. The path for external water and oxygen to invade the OLED device along the light emitting layer 11 is extended, and the stability of the display panel is improved.

In the embodiment of the present disclosure, the channel 14 passes through the protective layer 110, the first source-drain metal layer 109, the dielectric insulating layer 108 and the first gate metal layer 107. The protective layer 110 includes a first protrusion portion 141a, the first protrusion portion 141a extends into the channel 14 and the first protrusion portion 141a is suspended from the first source-drain metal layer 109, and the first protrusion portion 141a and a sidewall 141b of the first source-drain metal layer 109 define the undercut structure 141. The dielectric insulating layer 108 includes a second protrusion portion 142a, the second protrusion portion 142a extends into the channel 14 and is suspended from the first gate metal layer 107, and the second protrusion portion 142a and a sidewall 142b of the first gate metal layer 107 define another undercut structure 142.

It should be noted that, in the embodiment of the present disclosure, the undercut structure 141 is defined as the first undercut structure 141, and the other undercut structure 142 is defined as the second undercut structure 142.

It can be understood that, in the embodiment of the present disclosure, the first undercut structure 141 and the second undercut structure 142 are formed on the sidewall of the channel 14 to further extend the path of the external water and oxygen through the transition area 10B. The path of the external water and oxygen to invade the OLED device along the light emitting layer 11 is extended, thereby improving the stability of the display panel.

In some embodiments, the channel 14 passes through the protective layer 110 and the first source-drain metal layer 109. The protective layer 110 includes a first protrusion portion 141a, the first protrusion portion 141a extends into the channel 14 and is suspended from the first source-drain metal layer 109, and the first protrusion portion 141a and a sidewall 141b of the first source-drain metal layer 109 define the undercut structure 141.

Furthermore, the array substrate structure 10 includes a base substrate 101, a buffer layer 102, an active layer 103, a first gate insulating layer 104, a second gate metal layer 105, a second gate insulating layer 106, a first gate metal layer 107, a dielectric insulating layer 108, a first source-drain metal layer 109, a protective layer 110, a second source-drain metal layer 111, a first flat layer 112, a second flat layer 113, and a pixel definition layer 114.

Specifically, the buffer layer 102 is disposed on the base substrate 101.

The active layer 103 is disposed on the buffer layer 102, and the active layer 103 is located in the display area 10C.

The first gate insulating layer 104 is disposed on the buffer layer 102, wherein a portion of the first gate insulating layer 104 is located in the display area 10C covers the active layer 103.

The second gate metal layer 105 is disposed on the first gate insulating layer 104 and the second metal layer 105 is located in the display area 10C.

The second gate insulating layer 106 is disposed on the first gate insulating layer 104, wherein a portion of the second gate insulating layer 106 located in the display area 10C covers the second gate metal layer 105.

The first gate metal layer 107 is disposed on the second gate insulating layer 106.

The dielectric insulating layer 108 is disposed on the first gate metal layer 107.

The first source-drain metal layer 109 is disposed on the dielectric insulating layer 108.

The protective layer 110 is provided on the first source-drain metal layer 109.

The second source-drain metal layer 111 is disposed on the protective layer 110 and the second source-drain metal layer 111 is located in the display area 11C.

The first flat layer 112 is disposed on the protective layer 110, wherein a portion of the first flat layer 112 located in the display area 10C covers the second source-drain metal layer 111, and a portion of the first flat layer 112 located in the transition area 10B extends along the protective layer 110 to an edge of the opening.

The second flat layer 113 is disposed on the first flat layer 112 and the second flat layer 113 covers a portion of the first flat layer 112 located in the transition area 10B.

The pixel definition layer 114 is disposed on a portion of the first flat layer 112 located in the display area 10C.

The channel 14 passes through the protective layer 110, the first source-drain metal layer 109, the dielectric insulating layer 108, and the first gate metal layer 107. The first protrusion portion 141a of the protective layer 110 and the sidewall 141b of the first source-drain metal layer 109 define a first undercut structure 141. The second protrusion portion 142a of the dielectric insulating layer 108 and the sidewall 142b of the first gate metal layer 107 define a second undercut structure 142.

In the embodiment, the first undercut structure 141 and the second undercut structure 142 are formed on the first source-drain metal layer 109 and the first gate metal layer 107 in the transition area 10B, so that the light emitting layer 11 is broken at the first undercut structure 141 and the second undercut structure 142. The path of the external water and oxygen to invade the OLED device along the light emitting layer 11 is extended, thereby further improving the stability of the display panel.

In some embodiments, the channel 14 passes through the protective layer 110, the first source-drain metal layer 109, the dielectric insulating layer 108, the first gate metal layer 107, and the second gate insulating layer 106. The first source-drain metal layer 109 includes a first protrusion portion 141a, the first protrusion portion 141a extends into the channel 14 and the first protrusion portion 141a is suspended from the protective layer 110. The first gate metal layer 107 includes a second protrusion portion 142a, the second protrusion portion 142a passes through and into the channel 14 and the second protrusion portion 142a is suspended from the dielectric insulating layer 108 and the second gate insulating layer 106. The protrusion portion 141a and the side wall 141b of the dielectric insulating layer 108 define an undercut structure 141. The second protrusion portion 142a and the side wall 142b of the second gate insulating layer 106 define another undercut structure 142.

The above arrangement is to form the first undercut structure 141 and the second undercut structure 142 on the dielectric insulating layer 108 and the second gate insulating layer 106 in the transition area 10B. The path for external water and oxygen to invade the OLED device along the light emitting layer 11 is extended, and the stability of the display panel is improved.

In addition, in some embodiments, the channel 14 passes through the protective layer 110, the first source-drain metal layer 109, the dielectric insulating layer 108, and the first gate metal layer 107. The first source-drain metal layer 109 includes a first protrusion portion 141a, the first protrusion portion 141a extends into the channel 14 and is suspended from the protective layer 110. The first gate metal layer 107 includes a second protrusion portion 142a, the second protrusion portion 142a extends into the channel 14 and is suspended from the dielectric insulating layer 108. The first protrusion portion 141a and the sidewall 142b of the dielectric insulating layer 108 define a first undercut structure 141.

The OLED display panel in the embodiment of the present disclosure forms the first undercut structure 141 and the second undercut structure 142 on the first source-drain metal layer 109 and the first gate metal layer 107 in the transition area 10B, so that the light emitting layer 11 breaks at the first undercut structure 141 and the second undercut structure 142. When the encapsulation layer 12 is used to protect the breakage of the light emitting layer 11, the path of external water and oxygen to invade the OLED device along the light emitting layer 11 is extended, and the stability of the display panel is improved.

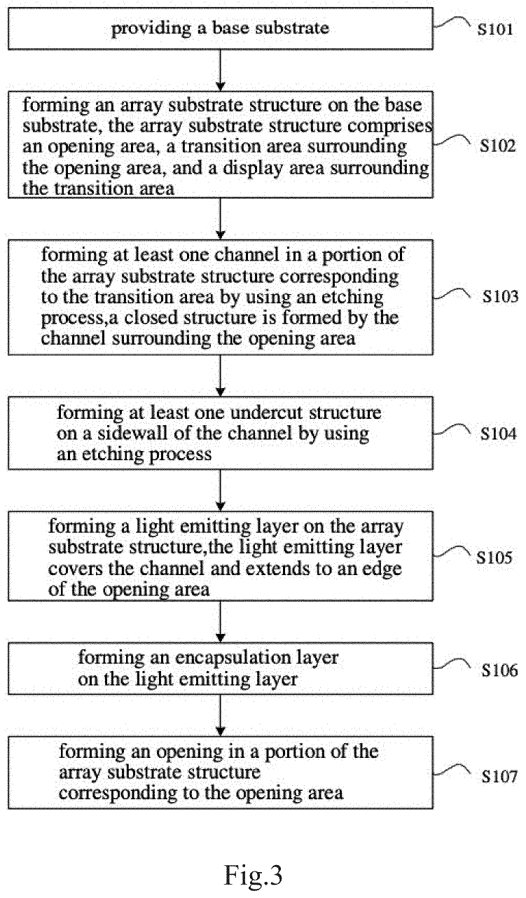

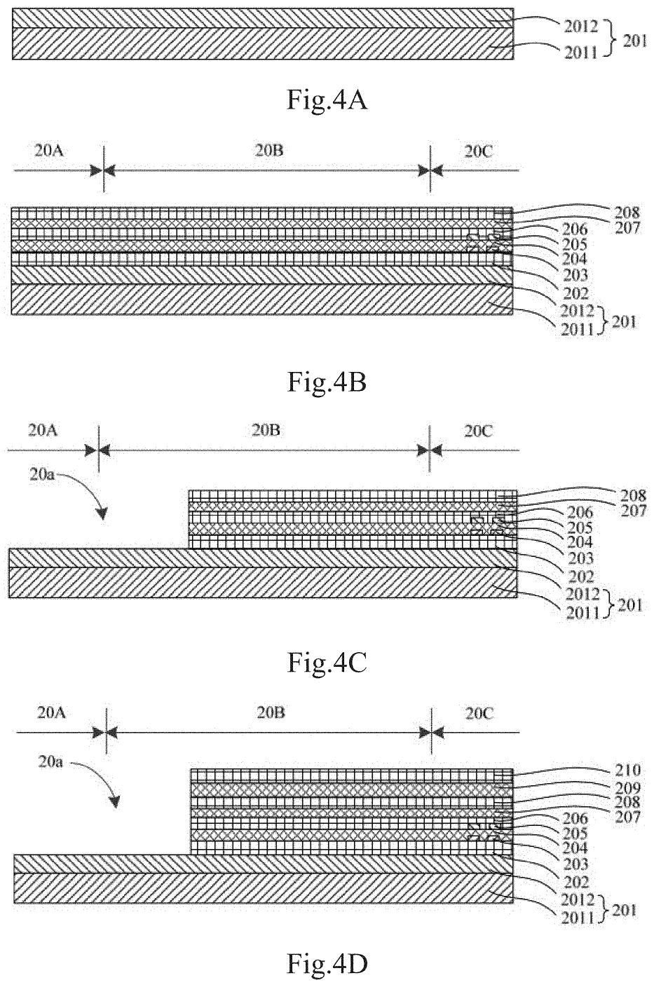

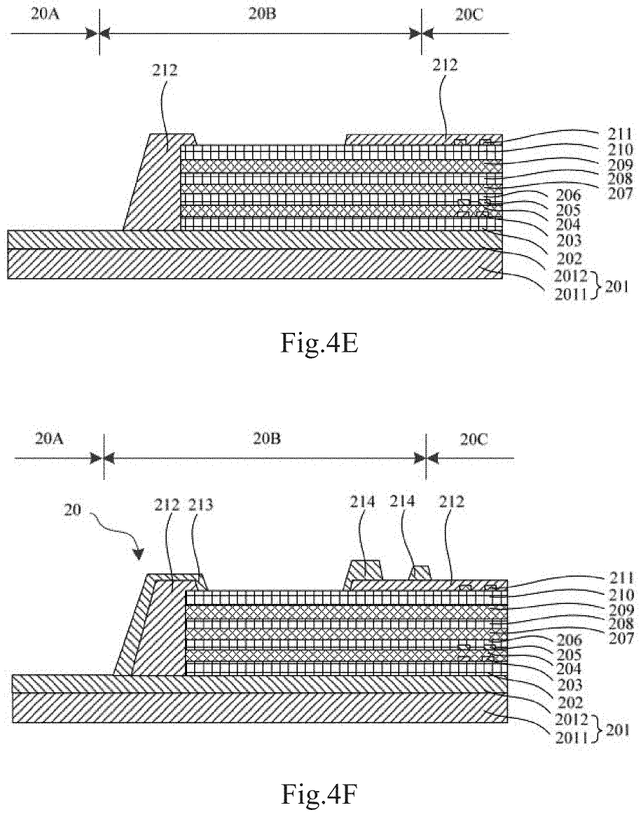

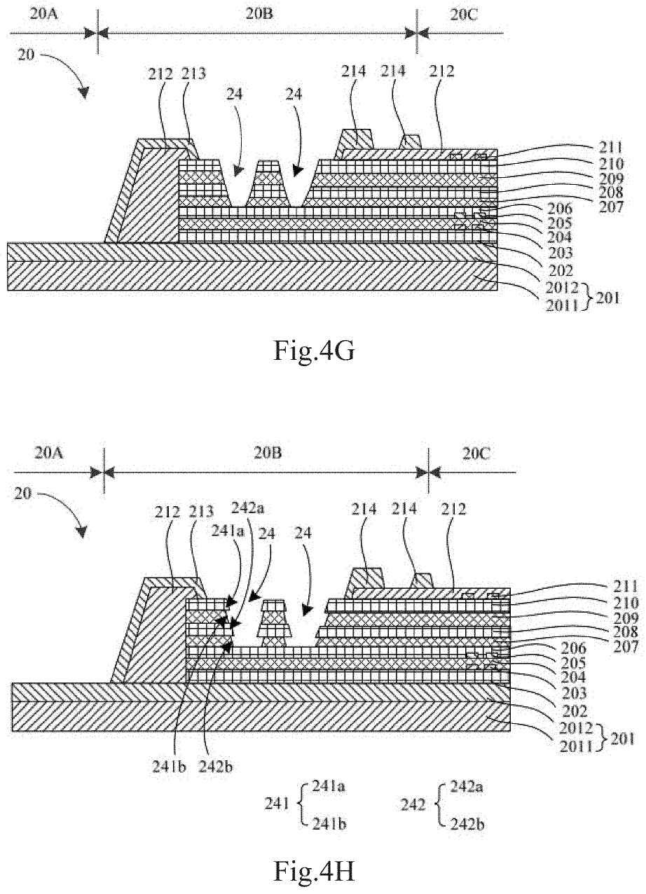

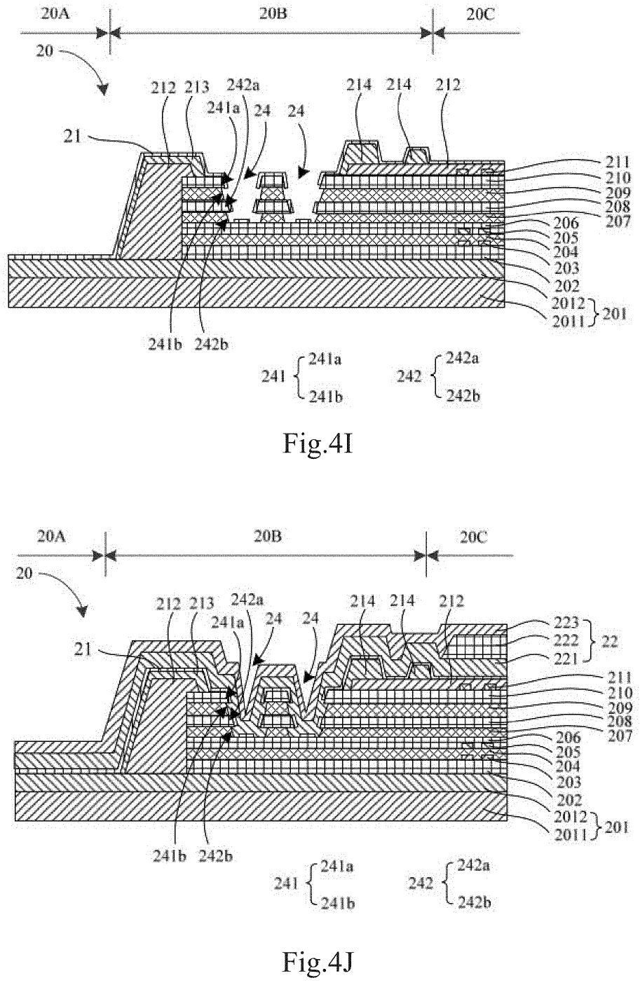

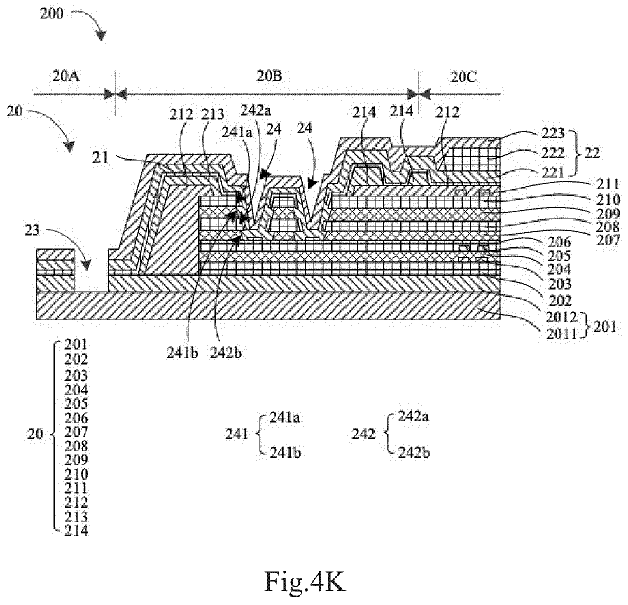

Refer to FIG. 3, and FIG. 4A to FIG. 4K. FIG. 3 is a flow chart of a method for manufacturing an OLED display panel according to an embodiment of the present disclosure. FIG. 4A to FIG. 4K are schematic structural diagrams obtained sequentially from steps S201 to S207 in the method for manufacturing an OLED display panel according to an embodiment of the present disclosure.

The present disclosure provides a preparation method of an OLED display panel, which comprises steps of:

Step S201, providing a base substrate.

Step S202, forming an array substrate structure on the base substrate, wherein the array substrate structure comprises an opening area, a transition area surrounding the opening area, and a display area surrounding the transition area.

Step S203, forming at least one channel in a portion of the array substrate structure corresponding to the transition area by using an etching process.

Step S204, forming at least one undercut structure on a sidewall of the channel by using an etching process.

Step S205, forming a light emitting layer on the array substrate structure, wherein the light emitting layer covers the channel and extends to an edge of the opening area.

Step S206, forming an encapsulation layer on the light emitting layer.

Step S207, forming an opening in a portion of the array substrate structure corresponding to the opening area

Thus, in the method for preparing the OLED display panel of the embodiment of the present disclosure, the undercut structure is formed in the transition area, so that the light emitting layer is broken at the undercut structure. When the encapsulation layer is used to protect the breakage of the light emitting layer, the path of the external water and oxygen invading the OLED device along the light emitting layer is increased, and the stability of the display panel is improved.

The preparation method of the OLED display panel 200 of the embodiment of the present disclosure is described in detail below.

In step S201, providing a base substrate 201.

Referring to FIG. 4A, the base substrate 201 specifically includes a substrate 2011 and a flexible substrate 2012. The substrate 2011 may be a rigid substrate, such as a glass substrate. The material of the flexible substrate 2012 may be polyimide. Then continue to step S202.

In step S202, forming an array substrate structure 20 on the base substrate 201, wherein array substrate structure 20 includes an opening area 20A, a transition area 20B surrounding the opening area 20A, and a display area 20C surrounding the transition area 20B.

Please refer to FIG. 4B to FIG. 4F. Step S202 specifically includes the following steps:

In step S2021, forming a buffer layer 202, a patterned active layer 203, a first gate insulating layer 204, a patterned first gate metal layer 205, a second gate insulating layer 206, a second gate metal layer 207, and dielectric insulating layer 208 on the base substrate 201 in sequence.

In step S2022, forming another opening 20a in the opening area 20A and at least passing through the dielectric insulating layer 208, the second gate metal layer 207, the second gate insulating layer 206, and the first gate insulating layer 204, and extending to the transition area 20B.

In step S2023, forming a first source-drain metal layer 209 and a protective layer 210 on the dielectric insulating layer 208 in sequence.

In step S2024, forming a patterned second source-drain metal layer 211 and a first flat layer 212 on the protective layer 210 in sequence.

In step S2025, forming a patterned second flat layer 213 and a pixel definition layer 214 on the first flat layer 212 in sequence to form the array substrate structure 20.

In step S2021, the active layer 203 and the first gate metal layer 205 are located in the display area 20C. The portion of the first gate insulating layer 204 located in the display area 20C covers the active layer 203. The portion of the second gate insulating layer 206 located in the display area 20C covers the first gate metal layer 205, as shown in FIG. 4B.

In step S2022, optionally, a laser cutting process or an etching process is used to make holes in the opening area 20A to form the other opening. The other opening passes through the dielectric insulating layer 208, the second gate metal layer 207, the second gate insulating layer 206, the first gate insulating layer 204, and the buffer layer 202, and extends to the transition area 20B, as shown in FIG. 4C Shown.

In step S2023, a first source-drain metal layer 209 and a protective layer 210 are sequentially formed on the dielectric insulating layer 208 by using a vapor deposition method, as shown in FIG. 4D.

In step S2024, a second source-drain metal layer 211 and a first flat layer 212 are sequentially formed on the protective layer 210 by using a vapor deposition method, and an etching process is used for patterning to form a patterned second source-drain metal layer 211 and a first flat layer 212, as shown in FIG. 4E.

The portion of the first flat layer 212 located in the display area 20C covers the second source-drain metal layer 211. The portion of the first flat layer 212 located in the transition are 20B extends along the protective layer 210 to the edge of the opening area 20A.

In step S2025, the second flat layer 213 and the pixel definition layer 214 are formed on the first flat layer 212 by using a vapor deposition method, and an etching process is used for patterning to form a patterned second flat layer 213 and a pixel definition layer 214, as shown in FIG. 4F.

The second flat layer 213 covers the portion of the first flat layer 212 located in the transition area 20B. The patterned pixel definition layer 214 is located on the portion of the first flat layer 212 located on the display area 20C. Then continue to step S203.

In step S203, an etching process is used to form at least one channel 24 in the portion of the array substrate structure 20 corresponding to the transition area 20B, and the channel 24 forms a closed structure around the opening area 20A.

Refer to FIG. 4G. Specifically, an etching process is used to form at least one channel 24 in the portion of the array substrate structure 20 corresponding to the transition area 20B, and the channel 24 forms a closed structure around the opening area 20A. The channel 24 passes through the protective layer 210, the first source-drain metal layer 209, the dielectric insulating layer 208, and the second gate metal layer 207 of the transition area 20B.

Optionally, the channel 24 is formed by a dry etching process. Then continue to step S204.

In step S204, at least one undercut structure 241 is formed on the sidewall of the channel 24 by using an etching process.

Refer to FIG. 4H. Specifically, a wet etching process is used to etch the sidewall of the channel 24 to form the undercut structure 241.

Furthermore, using an acid solution as an etching solution, a wet etching process is used to etch the sidewall of the channel 24 to form an undercut structure. The protective layer 210 includes a first protrusion portion 241a. The first protrusion portion 241a extends into the channel 24 and is suspended from the first source-drain metal layer 209. The first protrusion portion 241a and the sidewall 241b of the first source-drain metal layer 209 define the undercut structure 241. The dielectric insulating layer 208 includes a second protrusion portion 242a. The second protrusion portion 242a extends into the channel 24 and is suspended from the first gate metal layer 207. The second protrusion portion 242a and the sidewall 242b of the first gate metal layer 207 define another undercut structure 242.

It should be noted that, in the embodiment of the present disclosure, the undercut structure 241 is defined as the first undercut structure 241, and the other undercut structure 242 is defined as the second undercut structure 242.

Optionally, the acidic etching solution is one or more mixed solutions of acidic solutions such as phosphoric acid, nitric acid, and acetic acid. In addition, in some embodiments, according to the nature of the film to be etched, an alkaline solution may also be used as an etching solution, which is not redundantly repeated here.

Since the selection ratio of the acidic etching solution to the metal layer is greater than that of the inorganic layer. Specifically, the selection ratio of the metal layer to the inorganic layer is greater than 10. When the acidic solution is used as the etching solution, the etching rate of the first source-drain metal layer 209 and the second gate metal layer 207 is greater than that of the protective layer 210 and the dielectric insulating layer 208. Thus, a first undercut structure 241 and a second undercut structure 242 are formed on the first source-drain metal layer 209 and the second gate metal layer 207.

In addition, in some embodiments, a dry etching process may also be used to form the first undercut structure 241 and the second undercut structure 242 on the first source-drain metal layer 209 and the second gate metal layer 207.

Optionally, the etching gas used in the dry etching is chlorine-containing gas. When the first undercut structure 241 and the second undercut structure 242 are formed on the metal layer by dry etching, the selection ratio of the metal layer to the inorganic layer is greater than 5. Therefore, the etching process can be selected according to the actual application requirements, which is not redundantly repeated here.

In some embodiments, when an undercut structure is formed on the inorganic layer such as the dielectric insulating layer 208 and/or the second gate insulating layer 206, a dry etching process is used to form the undercut structure.

Optionally, the etching gas used in the dry etching is fluorine-containing gas. When dry etching is used to form an undercut structure on the inorganic layer, the selection ratio of the inorganic layer to the metal layer is greater than 10. Then continue to step S205.

In step S205, a light emitting layer 21 is formed on the array substrate structure 20, and the light emitting layer 21 covers the channel 24 and extends to the edge of the opening region 20A.

Refer to FIG. 4I. Specifically, a light emitting layer 21 is formed on the array substrate structure 20 by using an evaporation process. After the light emitting layer 21 is formed, a first undercut structure 241 and a second undercut structure 242 are formed on the first source-drain metal layer 209 and the second gate metal layer 207. As a result, the light emitting layer 21 is broken under stress. Then continue to step S206.

In step S206, an encapsulation layer 22 is formed on the light emitting layer 21.

Refer to FIG. 4J. Specifically, a first inorganic layer 221, an organic layer 222, and a second inorganic layer 223 are sequentially formed on the light emitting layer 21 by using a vapor deposition method to form the encapsulation layer 22, wherein the organic layer 222 is located in the display area 20C. Then continue to step S207.

In step S207, an opening 23 is formed in the portion of the array substrate structure 20 corresponding to the opening area 20A.

Refer to FIG. 4K. Specifically, a laser cutting process is used to form the opening 23, and the opening 23 passes through the encapsulation layer 22, the light emitting function layer 21 and the buffer layer 202.

In this way, the preparation method of the OLED display panel 200 of the embodiment of the present disclosure is completed.

The preparation method of the OLED display panel 200 in the embodiment of the present disclosure is to form the first undercut structure 241 and the second undercut structure 242 on the first source-drain metal layer 209 and the second gate metal layer 207 in the transition region 20B, so that the light emitting layer 21 breaks under stress. When the encapsulation layer 22 is used to protect the breakage of the light emitting layer 21, the path of the external water and oxygen invading the OLED device along the light emitting layer 21 is extended, and the stability of the display panel is improved.

Compared with the OLED display panel in the prior art, in the OLED display panel of the present disclosure, the undercut structure is provided on the metal layer of the transition area, so that the light emitting layer is broken under the effect of stress. When the encapsulation layer protects the breakage of the light-emitting function layer, the path of external water and oxygen intruding into the OLED device along the breakage of the light emitting layer is extended, and the stability of the display panel is improved.

It can be understood that, for a person of ordinary skill in the art, equivalent replacements or changes can be made according to the technical solution of the present disclosure and its inventive concept. All changes or substitutions should fall within the protection scope of the claims attached to the present disclosure.

1. An organic light-emitting diode (OLED) display panel, comprising:
an array substrate structure, a light emitting layer, and an encapsulation layer arranged in sequence, wherein the array substrate structure comprises an opening area, a transition area surrounding the opening area, and a display area surrounding the transition area, and an opening is formed in a portion of the array substrate structure corresponding to the opening area;
wherein at least one channel is formed in a portion of the array substrate structure corresponding to the transition area, a closed structure is formed by the channel surrounding the opening, and at least one undercut structure is provided on a sidewall of the channel;
wherein the light emitting layer and the encapsulation layer cover the channel and extend to an edge of the opening, and a fault structure is formed at the undercut structure by the light emitting layer; and
wherein the array substrate structure includes a base substrate, a buffer layer, a first gate metal layer, a dielectric insulating layer, a first source-drain metal layer, and a protective layer arranged in sequence, and the channel at least passes through the protection layer and the first source-drain metal layer.

2. The OLED display panel according to claim 1, wherein the protective layer includes a first protrusion portion, the first protrusion portion extends into the channel and is suspended from the first source-drain metal layer, and the first protrusion portion and a sidewall of the first source-drain metal layer define the undercut structure.

3. The OLED display panel according to claim 1, wherein the channel passes through the protective layer, the first source-drain metal layer, the dielectric insulating layer, and the first gate metal layer;
the protective layer includes a first protrusion portion, the first protrusion portion extends into the channel and is suspended from the first source-drain metal layer, and the first protrusion portion and a sidewall of the first source-drain metal layer define the undercut structure; and
the dielectric insulating layer includes a second protrusion portion, the second protrusion portion extends into the channel and is suspended from the first gate metal layer, and the second protrusion portion and a sidewall of the first gate metal layer define another undercut structure.

4. The OLED display panel according to claim 1, wherein the channel passes through the protective layer, the first source-drain metal layer, the dielectric insulating layer, and the first gate metal layer;
the first source-drain metal layer includes a first protrusion portion, the first protrusion portion extends into the channel and is suspended from the protective layer;
the first gate metal layer includes a second protrusion portion, the second protrusion portion extends into the channel and is suspended from the dielectric insulating layer; and
the first protrusion portion and a sidewall of the dielectric insulating layer define the undercut structure.

5. The OLED display panel according to claim 3, wherein the array substrate structure includes:
an active layer disposed on the buffer layer and located in the display area;
a first gate insulating layer disposed on the buffer layer, wherein a portion of the first gate insulating layer located in the display area covers the active layer;
a second gate metal layer disposed on the first gate insulating layer and located in the display area;
a second gate insulating layer disposed on the first gate insulating layer, wherein a portion of the second gate insulating layer located in the display area covers the second gate metal layer;
the first gate metal layer disposed on the second gate insulating layer;
the dielectric insulating layer disposed on the first on the first gate metal layer;
the first source-drain metal layer disposed on the dielectric insulating layer;
the protective layer provided on the first source-drain metal layer;
a second source-drain metal layer disposed on the protective layer and located in the display area;
a first flat layer disposed on the protective layer, wherein a portion of the first flat layer located in the display area covers the second source-drain metal layer, and a portion of the first flat layer located in the transition area extends along the protective layer to an edge of the opening;
a second flat layer disposed on the first flat layer and covering a portion of the first flat layer located in the transition area; and
a pixel definition layer disposed on a portion of the first flat layer located in the display area.

6. An organic light-emitting diode (OLED) display panel, comprising:
an array substrate structure, a light emitting layer, and an encapsulation layer arranged in sequence, wherein the array substrate structure comprises an opening area, a transition area surrounding the opening area, and a display area surrounding the transition area, and an opening is formed in a portion of the array substrate structure corresponding to the opening area;
wherein at least one channel is formed in a portion of the array substrate structure corresponding to the transition area, a closed structure is formed by the channel surrounding the opening, and at least one undercut structure is provided on a sidewall of the channel; and
wherein the light emitting layer and the encapsulation layer cover the channel and extend to an edge of the opening, and a fault structure is formed at the undercut structure by the light emitting layer.

7. The OLED display panel according to claim 6, wherein the array substrate structure includes a first gate metal layer, a dielectric insulating layer, a first source-drain metal layer, and a protective layer arranged in sequence, and the channel at least passes through the protection layer and the first source-drain metal layer.

8. The OLED display panel according to claim 7, wherein the channel passes through the protective layer, the first source-drain metal layer;
the protective layer includes a first protrusion portion, the first protrusion portion extends into the channel and is suspended from the first source-drain metal layer, and the first protrusion portion and a sidewall of the first source-drain metal layer define the undercut structure.

9. The OLED display panel according to claim 7, wherein the channel passes through the protective layer, the first source-drain metal layer, the dielectric insulating layer, and the first gate metal layer;
the protective layer includes a first protrusion portion, the first protrusion portion extends into the channel and is suspended from the first source-drain metal layer, and the first protrusion portion and a sidewall of the first source-drain metal layer define the undercut structure; and
the dielectric insulating layer includes a second protrusion portion, the second protrusion portion extends into the channel and is suspended from the first gate metal layer, and the second protrusion portion and a sidewall of the first gate metal layer define another undercut structure.

10. The OLED display panel according to claim 7, wherein the channel passes through the protective layer, the first source-drain metal layer, the dielectric insulating layer, and the first gate metal layer;
the first source-drain metal layer includes a first protrusion portion, the first protrusion portion extends into the channel and is suspended from the protective layer;
the first gate metal layer includes a second protrusion portion, the second protrusion portion extends into the channel and is suspended from the dielectric insulating layer; and
the first protrusion portion and a sidewall of the dielectric insulating layer define the undercut structure.

11. The OLED display panel according to claim 9, wherein the array substrate structure includes:
a base substrate;
a buffer layer disposed on the base substrate;
an active layer disposed on the buffer layer and located in the display area;
a first gate insulating layer disposed on the buffer layer, wherein a portion of the first gate insulating layer located in the display area covers the active layer;
a second gate metal layer disposed on the first gate insulating layer and located in the display area;
a second gate insulating layer disposed on the first gate insulating layer, wherein a portion of the second gate insulating layer located in the display area covers the second gate metal layer;
the first gate metal layer disposed on the second gate insulating layer;
the dielectric insulating layer disposed on the first gate metal layer;
the first source-drain metal layer disposed on the dielectric insulating layer;
the protective layer provided on the first source-drain metal layer;
a second source-drain metal layer disposed on the protective layer and located in the display area;
a first flat layer disposed on the protective layer, wherein a portion of the first flat layer located in the display area covers the second source-drain metal layer, and a portion of the first flat layer located in the transition area extends along the protective layer to an edge of the opening;
a second flat layer disposed on the first flat layer and covering a portion of the first flat layer located in the transition area; and
a pixel definition layer disposed on a portion of the first flat layer located in the display area.

12. A preparation method of an OLED display panel, comprising steps of:
providing a base substrate;
forming an array substrate structure on the base substrate, wherein the array substrate structure comprises an opening area, a transition area surrounding the opening area, and a display area surrounding the transition area;
forming at least one channel in a portion of the array substrate structure corresponding to the transition area by using an etching process, wherein a closed structure is formed by the channel surrounding the opening area;
forming at least one undercut structure on a sidewall of the channel by using an etching process;
forming a light emitting layer on the array substrate structure, wherein the light emitting layer covers the channel and extends to an edge of the opening area;
forming an encapsulation layer on the light emitting layer; and
forming an opening in a portion of the array substrate structure corresponding to the opening area.

13. The preparation method of the OLED display panel according to claim 12, wherein forming at least one undercut structure on a sidewall of the channel by using an etching process comprises step of:
adopting a wet etching process to etch the sidewall of the channel to form the undercut structure.

14. The preparation method of the OLED display panel according to claim 13, wherein forming an array substrate structure on the base substrate comprises steps of:
providing a base substrate;
forming a buffer layer on the base substrate;
forming an active layer on the buffer layer by patterning, wherein the active layer is located in the display area;
forming a first gate insulating layer on the buffer layer, wherein a portion of the first gate insulating layer located in the display area covers the active layer;
forming a first gate metal layer on the first gate insulating layer by patterning, wherein the first gate metal layer is located in the display area;
forming a second gate insulating layer on the first gate insulating layer, wherein a portion of the second gate insulating layer located in the display area covers the first gate metal layer;
forming a second gate metal layer on the second gate insulating layer;
forming a dielectric insulating layer on the second gate metal layer;
forming another opening in the opening area, wherein the opening at least passes through the dielectric insulating layer, the second gate metal layer, the second gate insulating layer, and the first gate insulating layer, and extends to the transition area;
forming a first source-drain metal layer on the dielectric insulating layer;
forming a protective layer on the first source-drain metal layer;
forming a second source-drain metal layer on the protective layer by pattering, wherein the second source-drain metal layer is located in the display area;
forming a first flat layer on the protective layer by patterning, wherein a portion of the first flat layer located in the display area covers the second source-drain metal layer, and a portion of the first flat layer located in the transition area extends along the protective layer to an edge of the opening;
forming a second flat layer on the first flat layer by patterning, wherein the second flat layer covers a portion of the first flat layer located in the transition area; and
forming a pixel definition layer on a portion of the first flat layer located in the display area by patterning.

15. The preparation method of the OLED display panel according to claim 14, wherein after forming a pixel definition layer on a portion of the first flat layer located in the display area by patterning, the step comprises:
forming at least one channel in a portion of the array substrate structure corresponding to the transition area by suing an etching process, wherein a closed structure is formed by the channel surrounding the opening area, and the channel passes through the protective layer, the first source-drain metal layer, the dielectric insulating layer, and the second gate metal layer;
wherein an acidic solution is used as an etching solution, and a sidewall of the channel is etched by a wet etching process to form the undercut structure; the protective layer includes a first protrusion portion, the first protrusion portion extends into the channel and is suspended from the first source-drain metal layer, and the first protrusion portion and a sidewall of the first source-drain metal layer define the undercut structure; the dielectric insulating layer includes a second protrusion portion, the second protrusion portion extends into the channel and is suspended from the first gate metal layer, and the second protrusion portion and a sidewall of the second gate metal layer define another undercut structure.
